(19) United States
(12) Patent Application Publication
(10) Pub. No.: US 2026/0123327 A1
(43) Pub. Date: Apr. 30, 2026

(54) SUBSTRATE PROCESSING APPARATUS AND METHOD

(71) Applicant: Samsung Electronics Co., Ltd., Suwon-si (KR)

(72) Inventors: Min Ho Choi, Suwon-si (KR); Kyung-Jin LEE, Seoul-si (KR); Jae Young JEON, Ulsan-si (KR); Jin Sung KIM, Suwon-si (KR); Kun Ho KWAK, Suwon-si (KR); Hoon Je SUNG, Suwon-si (KR); Dong Kyu LEE, Suwon-si (KR); Yoon Byeong CHAE, Suwon-si (KR); Yong Eon CHOI, Suwon-si (KR); Chan Seung CHOI, Suwon-si (KR)

(73) Assignees: Samsung Electronics Co., Ltd., Suwon-si (KR); NEXTIN, Inc., Hwaseong-si (KR)

(21) Appl. No.: 19/214,856

(22) Filed: May 21, 2025

(30) Foreign Application Priority Data
Oct. 29, 2024 (KR) 10-2024-0149889
Feb. 12, 2025 (KR) 10-2025-0018174

(51) Int. Cl. H01L 21/67; C23C 16/52

(52) U.S. Cl. CPC H10P 72/0414; C23C 16/52; H10P 72/0421; H10P 72/0436

(57) ABSTRACT

A substrate processing method for efficiently controlling charges induced into a substrate is provided. The substrate processing method comprises inserting a first substrate of a first condition into a first manufacturing apparatus, controlling charges of the first substrate by using a first discharge recipe in the first manufacturing apparatus, taking out the first substrate from the first manufacturing apparatus, inserting a second substrate of a second condition into a second manufacturing apparatus different from the first manufacturing apparatus, controlling charges of the second substrate by using a second discharge recipe different from the first discharge recipe in the second manufacturing apparatus, and taking out the second substrate from the second manufacturing apparatus.

### CROSS-REFERENCE TO RELATED APPLICATION

This application claims priority from Korean Patent Application No. 10-2024-0149889 filed on Oct. 29, 2024 and Korean Patent Application No. 10-2025-0018174 filed on Feb. 12, 2025 in the Korean Intellectual Property Office and all the benefits accruing therefrom under 35 U.S.C. 119, the contents of which in their entirety are herein incorporated by reference.

### BACKGROUND

### Technical Field

Example embodiments are directed to a substrate processing apparatus and a substrate processing method using the substrate processing apparatus.

### Description of the Related Art

As the integration of the semiconductor industry is increased, the size of a semiconductor device is reduced. A pattern size and a thin film thickness of the semiconductor device are reduced. Charges may be induced into a substrate by static electricity generated during a process. The induced charges may cause a pattern defect in a subsequent process.

The static electricity may be caused from, for example, using deionized water (DIW), charge transfer from a charged plastic material, or induction charging.

As a detailed example, when a cleaning solution is coated on a substrate while the substrate is being rotated, the relatively large amount of static electricity may be induced and concentrated on a central portion of the substrate due to centrifugal force. When the substrate rotates at a high speed, the velocity of air flow in the central portion of the substrate is three times higher than that in an edge portion of the substrate. Accordingly, static electricity is formed in the central portion of the substrate, in which centrifugal force is relatively weak. Charges may be induced on the surface and inside of the substrate due to the static electricity. The induced charges may cause a pattern defect (e.g., a pitting defect) or the like in a subsequent process.

In order to control the undesirable charges, the rotational speed of the substrate may be lowered when the cleaning solution is coated. However, in this way, a cleaning effect diminishes and/or the time required for the cleaning process is increased, thereby lowering efficiency.

### SUMMARY

Some example embodiments of the present disclosure is to provide a substrate processing method for efficiently controlling charges induced into a substrate.

Some example embodiments of the present disclosure is to provide a substrate processing apparatus for efficiently controlling charges induced into a substrate.

The present invention is not limited to the embodiments discussed in the present disclosure. Additional example embodiments of the present invention, which are not mentioned herein, will be clearly understood by those skilled in the art from the following description of the present disclosure.

According to some example embodiments of the present disclosure, a substrate processing method may include inserting a first substrate of a first condition into a first manufacturing apparatus; controlling charges of the first substrate by using a first charge control recipe in the first manufacturing apparatus; taking out the first substrate from the first manufacturing apparatus; inserting a second substrate of a second condition into a second manufacturing apparatus different from the first manufacturing apparatus; controlling charges of the second substrate by using a second charge control recipe different from the first charge control recipe in the second manufacturing apparatus; and taking out the second substrate from the second manufacturing apparatus.

According to some example embodiments of the present disclosure, a substrate processing method may include inserting a substrate into a wet cleaning apparatus; cleaning the substrate by spraying a cleaning solution onto the substrate in the wet cleaning apparatus; inserting the substrate into a first discharge apparatus; controlling charges in the substrate by using a first discharge recipe in the first discharge apparatus; delivering the substrate into a photo apparatus; performing a photo process step to the substrate in the photo apparatus; inserting the substrate into a second discharge apparatus different from the first discharge apparatus; controlling charges in the substrate by using a second discharge recipe different from the first discharge recipe in the second discharge apparatus; delivering the substrate into a dry etching apparatus; and performing a dry etching process step to the substrate in the dry etching apparatus.

According to some example embodiments of the present disclosure, a substrate processing apparatus may include a chamber; a support arranged in the chamber and configured to support the substrate; a gas supplier configured to supply a process gas in the chamber; a lamp arranged in the chamber and configured to generate charges from a process gas by receiving a lamp power; and a grid arranged on the support in the chamber, and configured to receive a control voltage and configured to control charges in the substrate by using the control voltage; and a controller, wherein the controller is configured to control the lamp power to a first magnitude, and subsequently control the lamp power to a second magnitude greater than the first magnitude to reduce the charges in the substrate.

A manufacturing method of a semiconductor process comprising providing a series of process steps for manufacturing a semiconductor device; providing a first substrate and a second substrate which are configured to be subject to the series of process steps; performing a first process step, which is one of the series of process steps, on the first substrate and the second substrate; after the performing of the first process step, performing a charge control process step, which is another of the series of process steps, on the first substrate and the second substrate; and after the performing of the charge control process step, performing a second process step, which is yet another of the series of process steps, on the first substrate and the second substrate. The first substrate and the second substrate are subject to the charge control process step by using a first recipe and a second recipe which are different from each other, respectively, and the first substrate and the second substrate are subject to the second process step by using a third recipe.

### BRIEF DESCRIPTION OF THE DRAWINGS

The above and other aspects and features of the present disclosure will become more apparent by describing in detail example embodiments thereof with reference to the attached drawings, in which:

FIG. 1 is a flow chart illustrating a substrate processing method according to some embodiments of the present disclosure;

FIG. 2 is a plan view illustrating a substrate processing apparatus according to some embodiments of the present disclosure;

FIG. 3 is a view illustrating a process chamber shown in FIG. 2;

FIG. 4 is a view illustrating a grid shown in FIG. 3;

FIG. 5 is a view illustrating an example embodiment of power supplied by a power supply shown in FIG. 3;

FIGS. 6 to 14 are flow charts illustrating a substrate processing method according to some embodiments of the present disclosure;

FIG. 15 is a view illustrating a substrate processing method according to some embodiments of the present disclosure;

FIG. 16 is a view illustrating a substrate processing method according to some embodiments of the present disclosure;

FIGS. 17 and 18 are views illustrating a substrate processing method according to some embodiments of the present disclosure;

FIG. 19 is a view illustrating a substrate processing method according to some embodiments of the present disclosure; and

FIG. 20 is a view illustrating a substrate processing method according to some embodiments of the present disclosure.

### DETAILED DESCRIPTION

Hereinafter, the embodiments of the present disclosure will be described in detail with reference to the accompanying drawings. Throughout the specification, like features and elements have been identified by the same or similar reference numerals and/or letters, and duplicate descriptions may be omitted for the purpose of simplicity and clarity. However, such repetition in the reference numerals and/or letters may not be limiting the present invention, and does not in itself dictate a relationship between the various embodiments and/or configurations discussed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second”in the specification or another claim).

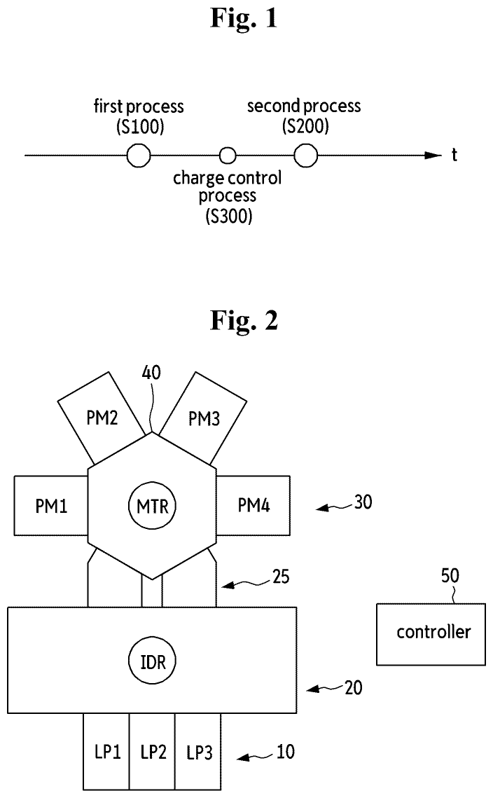

FIG. 1 is a flow chart illustrating a substrate processing method according to some embodiments of the present disclosure.

Referring to FIG. 1, in the substrate processing method according to some embodiments of the present disclosure, a charge control process S300 is performed before a second process S200 is performed after a first process S100 is performed. For example, each of the processes S100, S200 and S300 may be one of a series of process steps for manufacturing a semiconductor device. For example, the process S300 may be the next step of the process S100, and the process S200 may be the next step of the process S300. For example, the process S300 may directly follow process S100, and the process S200 may directly follow process S300, with no other processes in between, in a sequence of process steps for manufacturing a semiconductor device.

The charge control process S300 may be performed in a chamber (or apparatus) different from a chamber in which the first process S100 and the second process S200 are performed. For example, after the first process S100 is performed in a specific chamber, the charge control process S300 is not performed in the specific chamber. For example, after the charge control process S300 is performed in a specific chamber, the second process S200 is not performed in the specific chamber. For example, an apparatus, in which the charge control process step S300 is performed, may be different from an apparatus in which the process steps S100 and/or S200 are performed.

The charge control process step S300 may be a discharge process for removing charges induced in the substrate. However, the invention is not limited there to. In some embodiments, the charge control process step S300 may be utilized to obtain a plurality of substrates having substantially the same charge concentration (and/or substantially the same charge concentration gradient and/or the same charge polarity). The plurality of substrates may be subject to the same subsequent process steps S200. For example, the plurality of substrates may be simultaneously subject to the subsequent process step S100. For example, the charge control process step S300 may be a process for partially removing charges in the substrate.

The substrate may be a wafer. The substrate may be the base substrate itself (e.g., a bulk silicon substrate, a bulk germanium substrate, silicon on insulator (SOI), etc.), or may be a stack structure including a base substrate and layers (and/or patterns) formed on the base substrate.

A recipe of the charge control process (discharge process) step S300 may be determined by the first process S100. For example, the recipe may vary depending on whether the first process S100 is a cleaning process, a photo process, an SEM photographing, a DC test, etc. This is because the amount (number) and/or location (concentration gradient) and/or the polarity of the induced charges accumulated in the substrate may vary depending on the process type. Therefore, a recipe for the charge control process step may be set such that it is suitable for the process type.

The charges may be surface charges present on the surface of a substrate and/or embedded charges within the substrate. For example, charges may be classified into negative and positive charges based on their polarity. Both negative and positive charges may exist within a region of the substrate. The charge polarity of the region may be determined by the type of charge that is present in greater concentration. The number of charges in a substrate may be the net number which is the sum of the negative and positive charges (e.g., the absolute value of the difference between the number of negative charges and the number of positive charges). The concentration in a given region may be the net number per unit area, and the concentration may vary depending on the location within the substrate. The charge concentration gradient may be different between two substrates.

In addition, the recipe of the charge control process step S300 may vary depending on the type of apparatus in which the first process S100 is performed. For example, a plurality of kinds of apparatus may be used for the same process step. Among the plurality of kinds of equipment (or apparatus), a first equipment may be the equipment of a company A, and a second equipment may be the equipment of a company B. In this case, the amount/position of charges accumulated in the substrate after going through the first equipment among the plurality of kinds of equipment may be different from the amount/position of charges accumulated in the substrate after going through the second equipment. In even the case of the plurality of kinds of equipment of the same company, the amount/position of charges accumulated in the substrate may vary depending on which equipment has performed the cleaning process. Therefore, the recipe for discharging the substrate going through the first equipment and the recipe for discharging the substrate going through the second equipment may be different from each other. For example, if two substrate having the same structure and/or the same condition are processed by the same process recipe (of e.g., the first process step S100) in two different apparatuses respectively, the amount/position of charges accumulated in a substrate may be different from that of the other substrate. Therefore, the recipes for the charge control process step S300 for the two substrates may be different from each other.

In addition, if two substrates have different structures for some reason, the recipes for the charge control process step S300 for the two substrates may be different from each other. For example, the recipe for the discharge process may vary depending on a type of (or amount of, or thickness of) a film material in which charges are accumulated in the substrate that has gone through the first process S100. For example, the recipe may vary depending on the exposed amount or thickness of materials (e.g., two or more kinds of layer or pattern) on the substrate.

Alternatively, the two substrates having the different structure may be obtained by two different ones of a series of process steps for manufacturing a semiconductor device. For example, the recipe may vary depending on whether the film material (or the film material located at the top of the substrate) exposed on the substrate is an oxide film or a nitride film. The oxide film may have relatively more negative charges accumulated therein than the nitride film. For example, the charge control process time may be different. It may take, e.g., 20 seconds to reduce the negative charges in the oxide film to a desirable low level, while only, e.g., 10 seconds may be needed to achieve a similar reduction in the nitride film. In addition, power supplied to a lamp of a charge control device, which will be described later, may be different. When a first power is appropriate to remove the negative charges in the oxide film, a second power smaller than the first power may be appropriate to remove the negative charges in the nitride film.

Alternatively, when the film material (or the film material located at the top of the substrate) exposed on the substrate is a photoresist or an anti-reflective film, the power supplied to the lamp of the charge control device may be varied over time during the charge control process. For example, when the power supplied to the lamp is strong, the photoresist may shrink. Accordingly, the power supplied to the lamp may vary over time. For example, the power supplied to the lamp may be increased gradually (in a stepwise manner or linearly). Power of a first magnitude may be supplied to the lamp to cure a surface of the photoresist, and subsequently power of a second magnitude greater than the first magnitude may be supplied to the lamp. However, the invention is not limited thereto. For example, the power supplied to the lamp may be lowered gradually, e.g., causing a shift from high temperature to low temperature.

To customize the charge control process step S300 based on the type of the previously performed process and/or the condition of the substrate, the charge control process S300 may be carried out in an independent chamber. For example, in order to perform the discharge process customized to the previous process and/or customized to the substrate, the discharge process is performed in a chamber different from the chamber in which the first process S100 and/or the second process S200 are performed. Since the charges are substantially removed from the substrate that has been subjected to the discharge process, a defect (e.g., a pitting defect) due to the charges does not occur in the subsequent process.

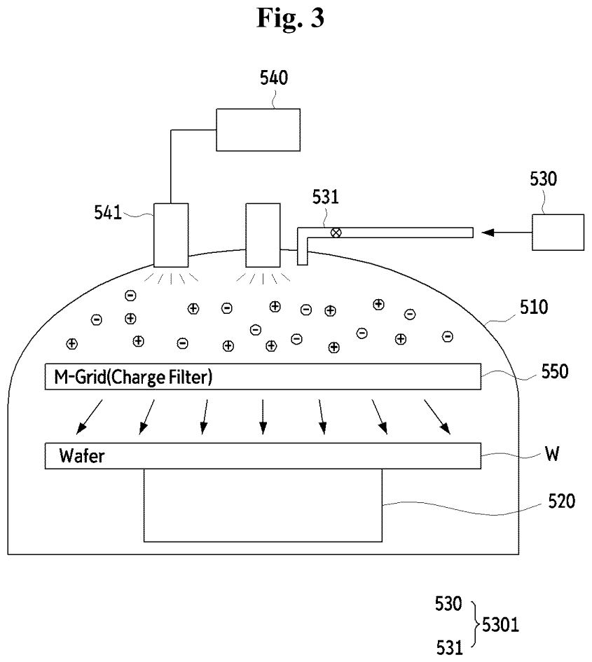

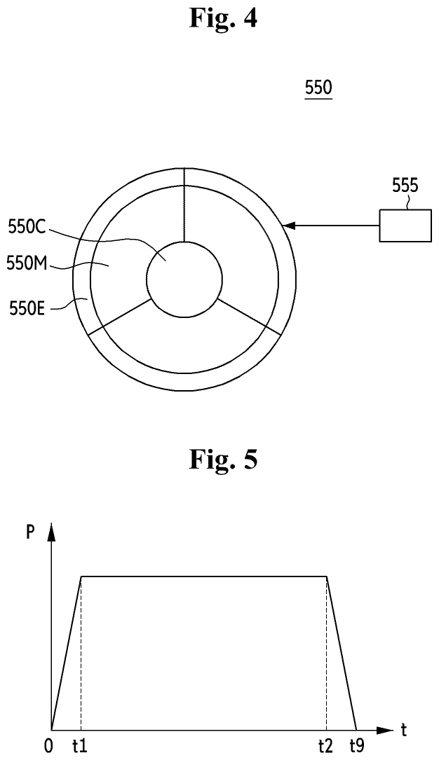

FIG. 2 is a view illustrating a substrate processing apparatus according to some embodiments of the present disclosure. FIG. 3 is a view illustrating the inside of a process chamber shown in FIG. 2. FIG. 4 is a view illustrating a grid shown in FIG. 3. FIG. 5 is a view illustrating an example embodiment of power supplied by a power supply shown in FIG. 3.

First, referring to FIG. 2, the substrate processing apparatus according to some embodiments of the present disclosure includes a load port 10, an index module 20, a buffer chamber 25, a transfer chamber 40, a process module 30, and a controller 50.

The load port 10 includes mounting tables (refer to LP1 to LP3) on which a container in which a plurality of substrates are accommodated is placed. The container may be, for example, a front opening integrated pod (FOUP), but is not limited thereto. The plurality of mounting tables may be arranged along one direction.

The index module 20 is arranged between the load port 10 and the buffer chamber 25. For example, the index module 20 includes a rail installed in an index chamber and an index robot IDR moving along the rail. The index robot IDR includes an arm and a hand, and picks up the substrate positioned at the load port 10 and transfers the picked-up substrate to the buffer chamber 25.

The buffer chamber 25 temporarily stores the substrate delivered by the index robot of the index module 20. Also, the buffer chamber 25 may temporarily store the substrate in which a preset process has been completed in at least one of process chambers PM1, PM2, PM3 and PM4.

A transfer robot MTR moving inside is installed in the transfer chamber 40.

The transfer robot MTR may transfer the substrate from the buffer chamber 25 to the process chamber (any one of PM1, PM2, PM3 and PM4). Alternatively, the transfer robot MTR may transfer the substrate from the process chamber (any one of PM1, PM2, PM3 and PM4) to the buffer chamber 25. Alternatively, the transfer robot MTR may transfer the substrate from the process chamber (e.g., PM1) to another process chamber (e.g., PM4).

The process module 30 includes a plurality of process chambers PM1, PM2, PM3 and PM4. Each of the process chambers PM1, PM2, PM3 and PM4 may be a chamber for performing the discharge process. Each of the process chambers PM1, PM2, PM3 and PM4 may perform the discharge process by using the same recipe. Alternatively, some process chambers (e.g., PM1 and PM2) and the other process chambers (e.g., PM3 and PM4) may perform the discharge process by using different recipes from each other.

The controller 50 controls an operation of at least one of the load port 10, the index module 20, the buffer chamber 25, the transfer chamber 40 or the process module 30. Particularly, the controller 50 may control the discharge process in the process chambers PM1, PM2, PM3 and PM4 of the process module 30. The charges in the substrate may be removed or controlled by using a preset discharge recipe. The controller 50 may be a computer or a processor, such as a DSP, an FPGA, a CPU, a GPU, a microprocessor.

Terms such as apparatus, equipment, chamber, module, facility and the like may be used interchangeably to refer to a manufacturing apparatus in semiconductor manufacturing. The manufacturing apparatus may include a metrology apparatus, inspection apparatus and test apparatus as well as a typical substrate processing apparatus (such as an etching facility, a photo facility and the like). The term “manufacturing apparatus” also may refer to a part of a manufacturing apparatus. For example, as described in FIG. 2, the substrate processing apparatus (which is a manufacturing apparatus) may include subsidiary manufacturing apparatuses such as the modules and the chambers.

Referring to FIG. 3, a support 520 configured to support a substrate W is arranged in a process chamber 510, which may be one of the process chambers PM1, PM2, PM3 and PM4 in FIG. 2.

A gas supplier 5301 may be provided and include a storage 530 for storing process gas, and a pipe 531 and a nozzle for supplying the process gas into the process chamber 510. The process gas may be a non-reactive gas, for example, N2, Ar or the like, but is not limited thereto. The process gas may be a single type gas or a mixed gas. A flow rate may be 0.5 sccm to 10000 sccm, but is not limited thereto.

A lamp 541 configured to receive power is arranged in the process chamber 510. The lamp 541 is connected to a power supply 540 that supplies power. The power supply 540 may supply power having a fixed magnitude. For example, referring to FIG. 5, a time period of 0 to t1 is a rising period, a time period of t1 to t2 is a power supply period, and a time period of t2 to t9 is a falling period. As shown in FIG. 5, the power may be constantly maintained during the power supply period. The magnitude of power at the power supply period may be a value that is previously set. The magnitude of power may be adjusted in accordance with the structure and/or the condition of the substrate to be processed in the chamber 510. The magnitude of power may be, for example, a value previously determined depending on what process the substrate inserted into the process chamber 510 has previously gone through, or what equipment the substrate has gone through, or what film material is to be exposed. Unlike the shown example, the power may vary depending on time during the power supply period.

The lamp 541 may be a UV lamp, but is not limited thereto. Power supplied to the UV lamp may be 0.5V to 10,000V, but is not limited thereto.

Referring to FIGS. 3 and 4, a grid 550 is arranged between the support 520 and the lamp 541 in the process chamber 510. For example, the grid 550 may be formed in a substantially disk shape when viewed from above, and may be divided into a plurality of zones 550C, 550M and 550E. As shown in FIG. 4, the grid 550 may include a center zone 550C, a middle zone 550M, and an edge zone 550E. The middle zone 550M may surround the center zone 550C, and the edge zone 550E may surround the middle zone 550M. A control voltage supplier 555 may supply a control voltage bias (or control voltage) to the grid 550. The control voltage may have a preset constant value, or may vary depending on time (e.g., the voltage changes as time progresses). In addition, the same voltage may be applied to each of the zones 550C, 550M and 550E, or a different voltage may be applied to each of the zones 550C, 550M and 550E. For example, the control voltage bias may include a single voltage or a plurality of voltages. The control voltage bias may be configured such that each of the plurality of voltages is supplied to a corresponding zone of the grid 550.

An aperture ratio of the grid 550 may be 0.5% to 90%, but is not limited thereto. The aperture ratio of the grid refers to the proportion or ratio of the open (or aperture) areas to the total area of a grid 550 when viewed from above.

A gap between the grid 550 and the substrate W may be 10 mm to 500 mm, but is not limited thereto.

A pressure in the process chamber 510 may be at a vacuum level equal to or less than 5000 mTorr.

The discharge operation will be described with reference to FIG. 3. The substrate W is inserted into the process chamber 510 and seated on the support 520.

The gas supplier 5301 may supply process gas into the process chamber 510. Charges (positive charges and negative charges) are generated from the process gas by the lamp 541.

For example, when a positive voltage is applied to the grid 550, the negative charges on an upper portion of the grid 550 are collected around a hole of the grid 550. Accordingly, a density of the positive charges is increased in a lower portion of the grid 550. As a result, the negative charges in the substrate W are neutralized.

For example, when a negative voltage is applied to the grid 550, the positive charges on the upper portion of the grid 550 are collected around the hole of the grid 550. Accordingly, the density of the negative charges is increased in the lower portion of the grid 550. As a result, the positive charges in the substrate W are neutralized.

For example, a different voltage may be applied to each zone of the grid 550. For example, the positive voltage may be applied to the center zone 550C and the middle zone 550M of the grid 550, and the negative voltage may be applied to the edge zone 550E of the grid 550. In this case, the negative charges located in the center/middle zone of the substrate W may be removed or reduced, and the positive charges located in the edge zone of the substrate W may be removed or reduced.

For example, the negative voltage may be applied to the center zone 550C of the grid 550, and the positive voltage may be applied to the middle zone 550M and the edge zone 550E of the grid 550. In this case, the positive charges located in the center zone of the substrate W may be removed or reduced, and the negative charge located in the middle/edge zone of the substrate W may be removed or reduced.

For example, while the positive voltage (or the negative voltage) is applied to the plurality of zones of the grid 550, the magnitude of the positive voltage (or the negative voltage) applied to each of the plurality of zones 550C, 550M and 550E may be different.

In some embodiments, as variables such as the power supplied to the lamp 541, the control bias voltage supplied to the grid 550, the process time, the process pressure, and/or the flow rate of the process gas are adjusted, the amount (number) and the speed of the charge control in the substrate W may be changed. Therefore, the optimal charge control process step may be carried out based on the structure and/or condition of the substrate to be processed in chamber 510.

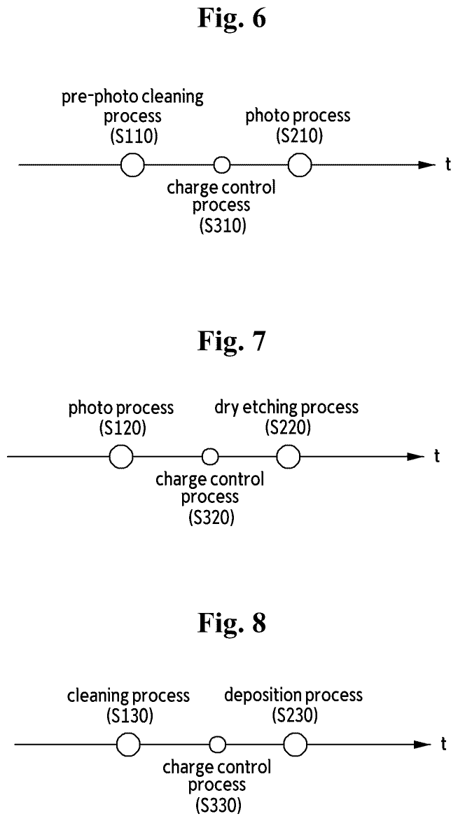

FIGS. 6 to 14 are flow charts illustrating a substrate processing method according to some embodiments of the present disclosure. For convenience of description, the description will be mainly focused on differences from those described with reference to FIGS. 1 to 5. The charge control processes described with reference to FIGS. 1 to 5 may be applicable to the charge control processes described hereinafter, unless they contradict any subsequent descriptions or if the context indicates otherwise.

Referring to FIG. 6, a pre-photo cleaning process S110 is performed. A cleaning solution is sprayed onto a substrate while the substrate is rotating in a wet cleaning chamber (or apparatus). Charges may be induced into the substrate by the pre-photo cleaning process S110.

Subsequently, a charge control process S310 is performed. The charges in the substrate may be neutralized in the discharge chamber (e.g., the process chamber 510) by using a recipe suitable for the substrate that has gone through the pre-photo cleaning process step S110. For example, similar to the manner to provide an optimal recipe as described above, a magnitude or shape of power supplied to a lamp (see 541 of FIG. 3) is determined and/or adjusted, and a magnitude of a control voltage bias supplied to the grid 550 may be determined and/or adjusted.

Next, a photo process S210 is performed. When the photo process S210 is performed in a photo facility (or apparatus) after the charge control process S310, a problem (e.g., an unacceptable critical dimension (CD), a defect, etc.) resulting from charges induced into the substrate may not occur. For example, by the charge control process step S310, the amount and distribution of the charges accumulated in the substrate may be controlled to be acceptable for the photo process step S210.

Referring to FIG. 7, a photo process step S120 is performed. After the photo process S120 is performed (or as a part of the photo process step S120), cleaning using a cleaning solution is performed. Accordingly, the charges are induced into the substrate.

Subsequently, a charge control process S320 may be performed. The charges in the substrate may be neutralized (or controlled) by using a recipe suitable for the cleaning performed in the photo process S120.

Next, a dry etching process S220 may be performed. Since the charges are removed (or controlled) by the charge control process step S320, a problem (e.g., an undesirable CD, a defect, etc.) may not occur during the dry etching process S220.

Referring to FIG. 8, a cleaning process S130 is performed. In the cleaning process S130, cleaning using a cleaning solution is performed. Accordingly, the charges may be induced into a substrate.

Next, a charge control process S330 is performed. The charges in the substrate may be neutralized (or controlled) by using a recipe suitable for the cleaning process S130.

Subsequently, a deposition process S230 of forming a predetermined film on the substrate is performed. Since the charges are removed (or controlled) by the charge control process S330, a problem (e.g., an insufficient thickness, a defect, etc.) may not occur during the deposition process S230.

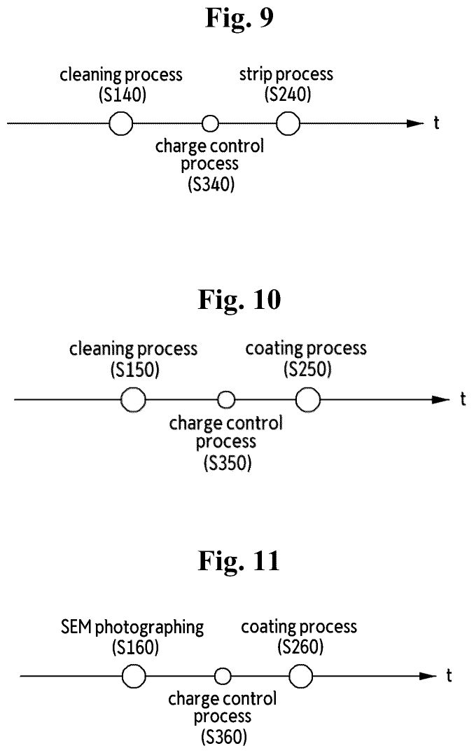

Referring to FIG. 9, a cleaning process S140 is performed. In the cleaning process S140, cleaning using a cleaning solution is performed. Accordingly, the charges may be induced into a substrate.

Next, a charge control process S340 is performed. The charges in the substrate may be neutralized (or controlled) by using a recipe suitable for the cleaning process S140.

Subsequently, a strip process S240 of forming a predetermined film on the substrate is performed. Since the charges are removed (or controlled) by the charge control process S340, a problem (e.g., unstrip, over strip, a defect, etc.) may not occur during the strip process S240.

Referring to FIG. 10, a cleaning process S150 is performed. In the cleaning process S150, cleaning using a cleaning solution is performed. Accordingly, the charges may be induced into a substrate.

Next, a charge control process S350 is performed. The charges in the substrate may be neutralized (or controlled) by using a recipe suitable for the cleaning process S150.

Next, a coating process S250 of forming a predetermined film on the substrate is performed. Since the charges are removed (or controlled) by the charge control process S350, a problem (e.g., an insufficient thickness, a defect, etc.) may not occur during the coating process S250.

Referring to FIG. 11, scanning electron microscope (SEM) photographing S160 is performed. The charges may be induced into a substrate during the SEM photographing S160.

Next, a charge control process S360 may be performed. The charges in the substrate may be neutralized (or controlled) by using a recipe suitable for the SEM photographing S160.

Subsequently, a coating process S260 of forming a predetermined film (e.g., photoresist, spin on hardmask (SOH), Tonen SilaZene (TOSZ), etc.) on the substrate is performed. Since the charges are removed (or controlled) by the charge control process S360, a problem (e.g., void, etc.) may not occur during the coating process S260.

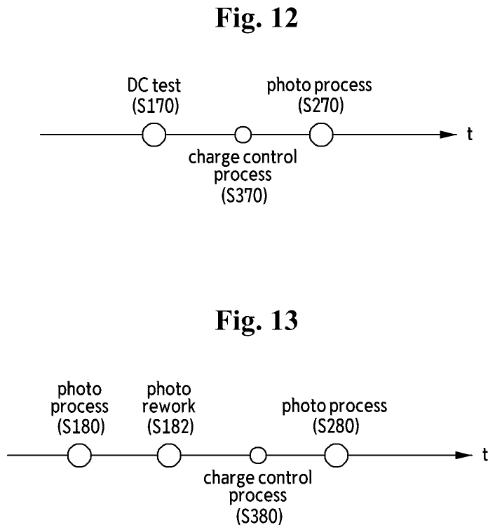

Referring to FIG. 12, a DC test S170 is performed. The DC test S170 is a test for measuring electrical characteristics of individual transistors, and applies current as DC to obtain a test result, thereby checking whether individual transistors operate normally. During the DC test S170, the charges may be induced into a substrate.

Next, a charge control process S370 is performed. The charges in the substrate may be neutralized (or controlled) by using a recipe suitable for the DC test S170.

Subsequently, a photo process S270 is performed. When the photo process S270 is performed after the charge control process S370 is performed, a problem (e.g., an insufficient CD standard, a defect, etc.) may not occur due to the charges induced into the substrate.

Referring to FIG. 13, a first photo process step S180 may be performed. A photo rework process step S182 may be performed, when a problem occurs in the first photo process step S180 or a result is out of spec (standard). For example, a first photoresist pattern generated in the first photo process step S180 is removed by, e.g., a strip process. Afterwards, cleaning may be performed.

Next, a charge control process S380 may be performed. The charges in the substrate may be neutralized (or controlled) by using a recipe suitable for the photo rework process step S182.

Subsequently, a second photo process S280 is performed. When the second photo process S280 is performed after the charge control process S380, a problem (e.g., an insufficient CD standard, a defect, etc.) resulting from the charges induced into the substrate may not occur. The photo process steps S180 and S280 may be performed by using the same photo mask. For example, if a first photoresist pattern obtained by the first process step S180 has not good quality, the first photoresist pattern may be removed, and a second photoresist pattern may be obtained by the second process step S280 to achieve a good quality. The first and second photoresist patterns may be substantially the same as each other. On the other hand, if the first photoresist pattern has good quality, the second process step S280 may not be performed. Accordingly, in a series of process steps for manufacturing a semiconductor device, the second process step S280 and the strip process step may be optional steps.

In an embodiment, the process step S182 may include determining whether to perform a sub-process step on a first substrate and a second substrate. The process step S182 may further include performing the sub-process step or skipping the sub-process step, based on the determination. The sub-process step may be the photo rework process step discussed above.

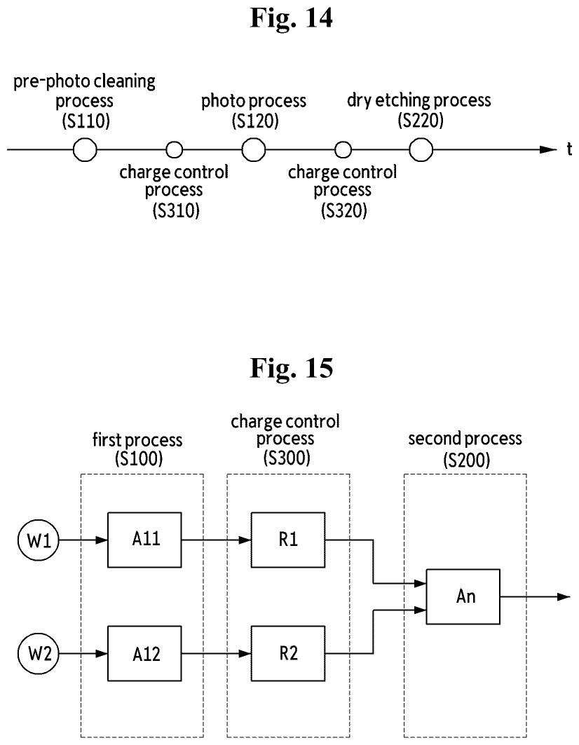

Referring to FIG. 14, a pre-photo cleaning process S110 is performed. In detail, a substrate is inserted into the wet cleaning chamber, and a cleaning solution may be sprayed onto the substrate to clean the substrate.

Next, the charge control process S310 is performed. In detail, the substrate is inserted into a first discharge chamber, and the charges in the substrate may be controlled by using a first discharge recipe.

Next, a photo process S210 is performed. In detail, the substrate is delivered to a photo facility so that the photo process is performed.

Next, the charge control process S320 is performed. In detail, the substrate is inserted into a second discharge chamber, and the charges in the substrate may be controlled by using a second discharge recipe.

Next, the dry etching process step S220 may be performed. In detail, the substrate may be delivered to a dry etching facility (or apparatus), so that dry etching is performed.

For example, the first discharge chamber in the charge control process S310 and the second discharge chamber in the charge control process S320 may be different from each other. Also, the first discharge recipe in the charge control process S310 and the second discharge recipe in the charge control process S320 may be different from each other. For example, referring to FIGS. 3 to 5, in the first discharge recipe, at least one variable value among the power supplied to the lamp 541, the control voltage supplied to the grid 550, the process time, the process pressure or the flow rate of the process gas may be different from a corresponding variable value in the second discharge recipe.

FIG. 15 is a view illustrating a substrate processing method according to some embodiments of the present disclosure. For convenience of description, the description will be mainly focused on differences from those described with reference to FIGS. 1 to 14.

Referring to FIG. 15, a first substrate W1 may be subject to a first process S100 in a first equipment A11. A second substrate W2 may be subject to the first process S100 in a second equipment A12. For example, the first equipment A11 and the second equipment A12 perform the same process step S100 in a sequence of process steps for manufacturing a semiconductor device, but the first and second apparatus A11 and A12 may be manufactured and provided by different apparatus manufacturers. For example, the first equipment A11 is manufactured by a company A, and the second equipment A12 is manufactured by a company B. In this case, the amount and/or concentration gradient and/or the polarity of charges induced into the first and second substrate W1 and W2 may be different from each other.

Subsequently, the first substrate W1 is inserted into a first discharge chamber R1, so that the charge control process S300 is performed by using a first discharge recipe. The second substrate W2 may be inserted into a second discharge chamber R2 different from the first discharge chamber R1, so that the charge control process S300 is performed by using a second discharge recipe different from the first discharge recipe.

For example, in the first discharge chamber R1, a first support, a first lamp arranged on the first support and configured to generate a first charge from a first gas, and a first grid arranged on the first support and configured to receive a first control voltage bias may be provided.

In the second discharge chamber R2, a second support, a second lamp arranged on the second support and configured to generate a second charge from a second gas, and a second grid arranged on the second support and configured to receive a second control voltage bias may be provided.

The difference between the first discharge recipe and the second discharge recipe may mean that at least one of the power supplied to the lamp, the control voltage supplied to the grid, the process time, the process pressure or the flow rate of the process gas is different.

For example, the first power supplied to the first lamp and the second power supplied to the second lamp may be different from each other.

In addition, the first discharge recipe may be configured such that the charge control process step is performed for a first time period, and the second discharge recipe may be configured such that the charge control process step is performed for a second time period different from the first time period.

Also, a first control voltage supplied to the first grid and a second control voltage supplied to the second grid may be different from each other.

Subsequently, the first substrate W1 is taken out from the first discharge chamber R1 and delivered to an equipment An. The second substrate W2 is also taken out from the second discharge chamber R2 and delivered to the equipment An. A second process S200 of the first substrate W1 and the second substrate W2 is performed in the equipment An. For example, the same process in a sequence of process steps for manufacturing a semiconductor device may be simultaneously performed onto the first substrate W1 and the second substrate W2 by using the same process recipe in the equipment An.

When the first substrate W1 and the second substrate W2 do not go through the discharge process S300, as the second process S200 of the first substrate W1 and the second substrate W2 is performed in the same equipment An, the process result of the first substrate W1 and the process result of the second substrate W2 may be different from each other. On the other hand, when the first substrate W1 and the second substrate W2 go through the discharge process S300, since the charges induced into the first substrate W1 and the charges induced into the second substrate W2 are removed (or controlled), such that there is no difference between the process result of the first substrate W1 and the process result of the second substrate W2. For example, the first and second discharge recipes may be prepared to control the charges in the first and second substrate W1 and W2 to obtain substantially the same charge concentration gradient by, e.g., adjusting at least one of the power supplied to the lamp, the control voltage supplied to the grid, the process time, the process pressure or the flow rate of the process gas, as described above. Accordingly, the process results of the first and second substrate W1 and W2 may be substantially the same as each other after the second process step S200.

Though it is previously described that the first and second substrate W1 and W2 are subject to the charge control process step S300 in the two different discharge apparatuses R1 and R2 respectively, the present invention is not limited thereto. The first and second substrate W1 and W2 may be subject to the charge control process step S300 in the same discharge apparatuses by using different charge control recipes respectively.

As described above, the charges of a first substrate having a first condition may be controlled in a first manufacturing apparatus by using a first discharge recipe, and the charges of a second substrate having a second condition may be controlled in a second manufacturing apparatus by using a second discharge recipe. The second condition may be different from the first condition. For example, the first substrate and the second substrate may be subject to different process conditions (e.g., two different equipment as discussed above) during a selected one of a series of process steps for manufacturing a semiconductor device, before the charge control process step.

In some embodiments, though the first substrate and the second substrate may be subject to the same process step, the result of the process in the two substrates may be unintentionally different from each other. For example, due to a substrate-to-substrate variation in a batch of substrates, the ratios of the exposed area of a first film (e.g., silicon oxide) to the exposed area of a second film (e.g., silicon nitride) in the two substrates may be different from each other. For example, a larger amount of charge may be induced in the first film compared to the second film. In another example, the polarity (e.g., positive) of the charges induced in the first film may be different from the polarity (e.g., negative) of the charges induced in the second substrate.

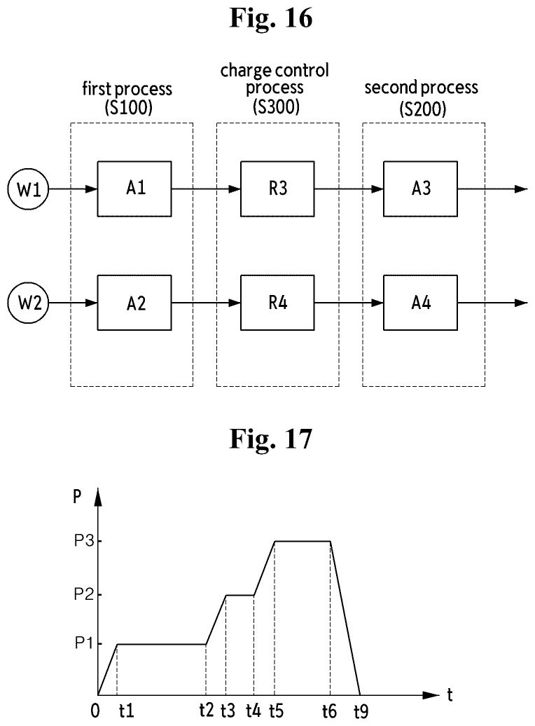

FIG. 16 is a view illustrating a substrate processing method according to some embodiments of the present disclosure. For convenience of description, the description will be mainly focused on differences from those described with reference to FIGS. 1 to 15.

Referring to FIG. 16, the first substrate W1 performs the first process S100 in an equipment A1. The second substrate W2 performs the first process S100 in an equipment A2.

A film material (or a film material located at the top of the substrate) exposed on the first substrate W1 may be a first film, and a film material (or a film material located at the top of the substrate) exposed on the second substrate W2 may be a second film different from the first film. For example, the first film may be an oxide film, and the second film may be a nitride film.

Alternatively, the film material (e.g., the oxide film) in which charges are mainly accumulated in the first substrate W1 and the film material (e.g., the nitride film) in which charges are mainly accumulated in the second substrate W2 may be different from each other.

Subsequently, the first substrate W1 is moved from the equipment A1 to a discharge chamber R3. The charge control process S300 for the first substrate W1 may be performed in the discharge chamber R3. The second substrate W2 is moved from the equipment A2 to a discharge chamber R4. The charge control process S300 for the second substrate W2 may be performed in the discharge chamber R4.

A discharge recipe in the discharge chamber R3 and a discharge recipe in the discharge chamber R4 are different from each other.

The oxide film may have relatively more negative charges accumulated therein than the nitride film. For example, the charge control process time may be different. When 20 seconds are appropriate to remove the negative charges in the oxide film, a shorter time (e.g., 10 seconds) may be appropriate to remove the negative charges in the nitride film. For example, the power supplied to the lamp of the charge control device may be different. When a first power is appropriate to remove the negative charges in the oxide film, a second power smaller than the first power may be appropriate to remove the negative charges in the nitride film.

Subsequently, the first substrate W1 is moved from the discharge chamber R3 to an equipment A3. The second substrate W2 may be moved from the discharge chamber R4 to an equipment A4, thereby performing the second process step S200.

The charges of the first substrate of the first condition (the charges of the first substrate being in the first condition) may be controlled in the first apparatus by using the first discharge recipe. The second substrate of the second condition (the second substrate being in the second condition) different from the first condition may be inserted into the second chamber different from the first chamber, and the charges of the second substrate may be controlled in the second apparatus by using the second discharge recipe different from the first discharge recipe.

In some embodiments, “the condition of the substrate is different” may mean that the film material (or the film material located at the top of the substrate) exposed on the substrate is different. For example, it may mean that the first substrate/the second substrate have gone through a different process before. For example, the first substrate may be subject to an optional process, but the second substrate may not. The optional process may be any one of wet cleaning, a photo process, DC test, and SEM photographing.

In an embodiment, the optional process may include determining whether to perform a sub-process step on a first substrate and a second substrate. The optional process may further include performing the sub-process step or skipping the sub-process step, based on the determination. The sub-process step may be any one of wet cleaning, a photo process, DC test, SEM photographing and so on.

In an embodiment, the second substrate of the second condition may perform another one of wet cleaning, a photo process, DC test, and SEM photographing. For example, “the condition of the substrate is different” may mean that the first substrate/the second substrate have gone through the same process step (for example, a cleaning process) in equipment of a different manufacturer. In this way, when the conditions of the substrates are different, the charges of the substrates are controlled by using different discharge recipes customized for the different conditions.

For example, a first discharge recipe may be configured such that the charge control process step is performed for a first time period, and a second discharge recipe may be configured such that the charge control process step is performed for a second time period different from the first time period.

For example, the magnitude of the power supplied to the first lamp used during the first discharge recipe and the magnitude of the power supplied to the second lamp used during the second discharge recipe may be different from each other.

For example, in one embodiment, the power supplied to the first lamp of the first discharge recipe has a fixed value, and the power supplied to the second lamp of the second discharge recipe may be varied over time. For example, the power supplied to the second lamp may be increased in a stepwise manner.

For example, the same voltage may be applied to the entire of the first grid when the first discharge recipe is used, and a different voltage may be applied to each of the plurality of zones (e.g., the zones 550C, 550M and 550E as discussed above) of the second grid when the second discharge recipe is used. For example, the first discharge recipe may be set to apply a first voltage to the entire first grid such that the same voltage is applied to the plurality of zones at a predetermined time. The second discharge recipe may be set to supply a plurality of different voltages to the second grid, and each voltage may be applied to a corresponding zone of the second grid at a predetermined time. Accordingly, the two substrates may have substantially the same charge concentration gradient after the charge control process step.

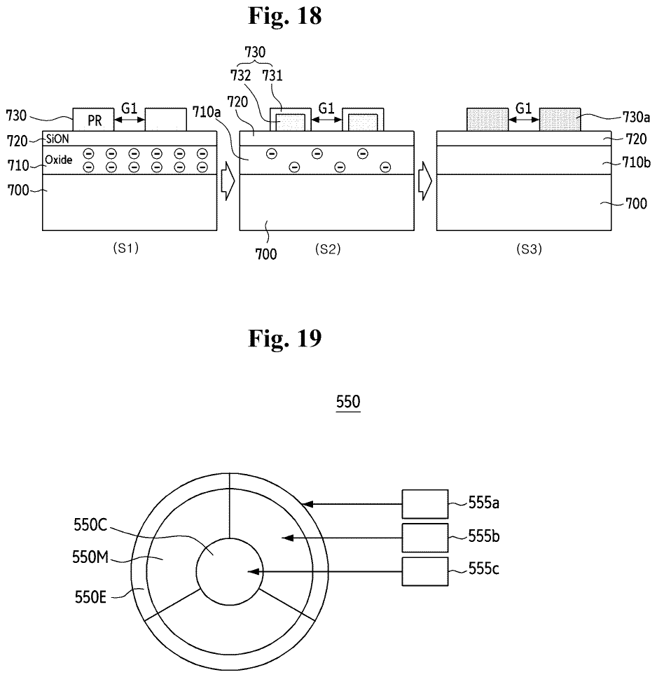

FIGS. 17 and 18 are views illustrating a substrate processing method according to some embodiments of the present disclosure. For convenience of description, the description will be mainly focused on differences from those described with reference to FIGS. 1 to 16.

The lamp power shown in FIG. 5 is constantly maintained. For example, a time period of t1 to t2 is a power supply period, and during the power supply period, the lamp power is constantly maintained.

The lamp power shown in FIG. 17 is varied over time or depending on time. For example, a time period of 0 to t1 may be a rising period, a time period of t1 to t6 may be a power supply period, and a time period of t6 to t9 may be a falling period. During the power supply period, the lamp power is varied depending on time. The lamp power may be increased in a stepwise manner in the time period of 0 to t6.

In detail, the power at the time period of t1 to t2 maintains a first magnitude of P1, and the power at the time period of t2 to t3 is increased from the first magnitude of P1 to a second magnitude of P2. The power at the time period of t3 to t4 is maintained at the second magnitude of P2, and the power at the time period of t4 to t5 is increased from the second magnitude of P2 to a third magnitude of P3. The power at the time period of t5 to t6 is maintained at the third magnitude of P3.

FIG. 17 illustrates that the power is increased in three steps, but is not limited thereto. For example, the power may be increased in two steps, or may be increased in four or more steps.

The damage to a film material on the substrate may be minimized using the lamp power (refer to P1) of a small magnitude. Subsequently, the charges in the substrate may be reduced using the greater lamp power (refer to P2 and P3). Reducing the charges in the substrate includes reducing the charges in films formed on the substrate.

FIG. 18 is a cross-sectional view illustrating stages of a charge control process step, which may be the process described with reference to FIG. 17. Referring to FIG. 18, a stage S1 shows a step before a charge control process is performed. An oxide film 710 and an oxynitride film 720 are sequentially stacked on a substrate 700. A photoresist pattern 730 is formed on the oxynitride film 720. A gap between adjacent photoresist patterns 730 is a distance G1. Negative charges are induced into the oxide film 710.

A stage S2 shows that the charge control process is performed with the power of the first magnitude P1 at the time period of t1 to t2. A surface 731 of the photoresist pattern 730 may be cured to reduce contraction of the photoresist pattern 730. The inside 732 of the photoresist pattern 730 is not sufficiently cured. The gap between the adjacent photoresist patterns 730 is maintained such that the distance G1 is not changed during the charge control process step. The negative charges in the oxide film 710a may be partially removed.

A stage S3 shows that the charge control process is performed with the power of the second magnitude P2 and the third magnitude P3 at the time period of t2 to t6. The inside 730a of the photoresist pattern 730 may be cured. The negative charges in the oxide film 710b may be sufficiently removed.

FIG. 19 is a view illustrating a substrate processing method according to some embodiments of the present disclosure. For convenience of description, the description will be mainly focused on differences from those described with reference to FIGS. 1 to 18.

Referring to FIG. 19, the grid 550 may be formed in a substantially disk shape, and may be divided into a plurality of zones 550C, 550M and 550E.

Control voltage suppliers 555a, 555b and 555c may independently supply control voltages to the grid 550. The control voltage supplier 555a may supply the control voltage to the edge zone 550E, the control voltage supplier 555b may supply the control voltage to the middle zone 550M, and the control voltage supplier 555c may supply the control voltage to the center zone 550C.

The control voltage suppliers 555a, 555b and 555c may apply the same voltage to the corresponding zones 550C, 550M and 550E, or may apply different voltages to the corresponding zones 550C, 550M and 550E.

The control voltage supplied to each of the corresponding zones 550C, 550M and 550E may have a preset constant value, or may vary over time or depending on time.

The amount/position of charges induced into the substrate may be different depending on what process the substrate has gone through before, what equipment the substrate has gone through, or what film material is exposed. The charges induced into the substrate in a customized type may be removed by adjusting the control voltage supplied to each of the plurality of zones 550C, 550M and 550E. The substrate may have a charge concentration gradient. The charges induced into the substrate may be removed or controlled by adjusting the control voltage bias independently supplied to each of the plurality of zones 550C, 550M and 550E. For example, each of different voltages may be supplied to a corresponding one of the zones to reduce or decrease the gradient.

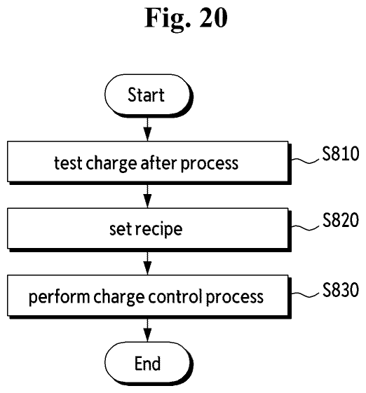

FIG. 20 is a view illustrating a substrate processing method according to some embodiments of the present disclosure.

Referring to FIG. 20, charges may be induced into a substrate after a previous process step. In a charge test process step S810, the charge polarity type, the charge amount and/or the charge concentration gradient in the substrate may be checked and determined. In this case, the previous process step may be any one of wet cleaning, a photo process, a DC test, and SEM photographing.

Next, a charge control recipe is set in accordance with a test result in a recipe setting process step S820. The charge control recipe may be customized in accordance with the result of the charge test process step S810 (e.g., the charge polarity type, the charge amount and/or the charge concentration gradient). For example, the recipe may vary depending on the type of manufacturing apparatus in which the previous process is performed. For example, the recipe may vary depending on the type of the film material in which charges are accumulated in the substrate. The recipe may also vary depending on the type of the film material exposed on the substrate.

Subsequently, a charge control process step S830 may be performed by using the recipe obtained in recipe setting process step S820.

While several example embodiments have been provided in the present disclosure, it should be understood that the disclosed devices, systems and methods might be embodied in many other specific forms without departing from the spirit or scope of the present invention. The present examples are to be considered as illustrative and not restrictive, and the intention is not to be limited to the details given herein. For example, the various elements or components may be combined or integrated in another device or system, or certain features may be omitted, or not implemented.

In addition, techniques, systems, subsystems, and methods described and illustrated in the various embodiments as discrete or separate may be combined or integrated with other systems, modules, techniques, or methods without departing from the scope of the present invention. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope of the invention.

What is claimed is:

1. A substrate processing method comprising:
inserting a first substrate of a first condition into a first manufacturing apparatus;
controlling charges of the first substrate by using a first charge control recipe in the first manufacturing apparatus;
taking out the first substrate from the first manufacturing apparatus;
inserting a second substrate of a second condition into a second manufacturing apparatus different from the first manufacturing apparatus;
controlling charges of the second substrate by using a second charge control recipe different from the first charge control recipe in the second manufacturing apparatus; and
taking out the second substrate from the second manufacturing apparatus.

2. The substrate processing method of claim 1, wherein:
the first substrate includes a first film and a second film materially different from the first film, and charges in the first film are controlled by using the first charge control recipe,
the second substrate includes the first film and the second film, and charges in the second film are controlled by using the second charge control recipe, and
a ratio of an exposed area of the first film to an exposed area of the second film in the first substrate is different from that in the second substrate.

3. The substrate processing method of claim 2, wherein the first film is an oxide film, and the second film is a nitride film.

4. The substrate processing method of claim 1,
wherein the first manufacturing apparatus includes:
a first support,
a first lamp arranged on the first support and configured to generate a first charge from a first gas during the controlling of charges in the first substrate, and
a first grid arranged on the first support and configured to receive a first control voltage bias, and
wherein the second manufacturing apparatus includes:
a second support,
a second lamp arranged on the second support and configured to generate a second charge from a second gas during the controlling of charges in the second substrate and
a second grid arranged on the second support and configured to receive a second control voltage bias.

5. The substrate processing method of claim 4, wherein:
during the controlling of charges of the first substrate, a magnitude of a first power is supplied to the first lamp,
during the controlling of charges of the second substrate, a magnitude of a second power is supplied to the second lamp, and
the magnitude of the first power is different from the magnitude of the first power.

6. The substrate processing method of claim 4, wherein the first charge control recipe includes controlling charges for a first time period, and
the second charge control recipe includes controlling charges for a second time period different from the first time period.

7. The substrate processing method of claim 4, wherein the first charge control recipe is configured to supply a first power to the first lamp which is a fixed value over time, and
the second charge control recipe is configured to supply a second power supplied to the second lamp which varies depending over time.

8. The substrate processing method of claim 7, wherein the second substrate includes a first film,
the second substrate of the second condition has a photoresist pattern arranged on the first film, and
the second charge control recipe is configured such that the second power is increased in a stepwise manner over time during the second charge control recipe.

9. The substrate processing method of claim 4, wherein the first control voltage bias is configured such that a single voltage is applied to an entirety of the first grid at a predetermined time during the controlling of charges of the first substrate,
the second grid is divided into a plurality of zones, and
the second control voltage bias is configured such that each of a plurality of different voltages is applied to a corresponding zone of the second grid at a predetermined time during the controlling of charges of the second substrate.

10. The substrate processing method of claim 1, further comprising:
performing a previous process step on the first substrate, before inserting of the first substrate into the first manufacturing apparatus; and
performing the previous process step on the second substrate, before inserting of the second substrate into the second manufacturing apparatus,
wherein the first condition is obtained by the previous process step, and the second condition is obtained by the previous process step.

11. A substrate processing method comprising:
inserting a substrate into a wet cleaning apparatus;
cleaning the substrate by spraying a cleaning solution onto the substrate in the wet cleaning apparatus;
inserting the substrate into a first discharge apparatus;
controlling charges in the substrate by using a first discharge recipe in the first discharge apparatus;
delivering the substrate into a photo apparatus;
performing a photo process step to the substrate in the photo apparatus;
inserting the substrate into a second discharge apparatus different from the first discharge apparatus;
controlling charges in the substrate by using a second discharge recipe different from the first discharge recipe in the second discharge apparatus;
delivering the substrate into a dry etching apparatus; and
performing a dry etching process step to the substrate in the dry etching apparatus.

12. The substrate processing method of claim 11,
wherein the second discharge apparatus includes:
a support,
a lamp arranged on the support, the second discharge apparatus configured to generate charges from a process gas during the control of charges by using the second discharge recipe, and
a grid arranged on the support and configured to receive a control voltage bias during the control of charges by using the second discharge recipe, and
wherein a power supplied to the lamp is configured to vary over time during the control of charges by using the second discharge recipe.

13. The substrate processing method of claim 12, wherein, during the control of charges by using the second discharge recipe:
the power of the lamp is controlled to have a first magnitude, and
subsequently, the power of the lamp is controlled to have a second magnitude greater than the first magnitude to reduce the charges of the substrate.

14. The substrate processing method of claim 13, wherein the substrate includes an oxide film and a photoresist pattern arranged on the oxide film.

15. The substrate processing method of claim 11, further comprising:
performing a photo rework process step after performing the photo process step; and
inserting the substrate into a third discharge apparatus different from the first discharge apparatus to control charges in the substrate by using a third discharge recipe different from the first discharge recipe.

16. The substrate processing method of claim 11, further comprising:
performing SEM photographing on the substrate; and
inserting the substrate into a fourth discharge apparatus different from the first discharge apparatus to control charges in the substrate by using a fourth discharge recipe different from the first discharge recipe.

17. The substrate processing method of claim 11, further comprising:
performing DC test on the substrate; and
inserting the substrate into a fifth discharge apparatus different from the first discharge apparatus to control charges in the substrate by using a fifth discharge recipe different from the first discharge recipe.

18. A substrate processing apparatus comprising:
a chamber;
a support arranged in the chamber and configured to support a substrate;
a gas supplier configured to supply a process gas in the chamber;
a lamp arranged in the chamber and configured to generate charges from the process gas by receiving a lamp power; and
a grid arranged on the support in the chamber, and configured to receive a control voltage bias and configured to control charges in the substrate by using the control voltage bias; and
a controller,
wherein the controller is configured to control the lamp power to have a first magnitude, and subsequently control the lamp power to have a second magnitude greater than the first magnitude to reduce the charges in the substrate.

19. The substrate processing apparatus of claim 18, wherein the controller is configured to maintain the first magnitude for a first time period and to maintain the second magnitude for a second time period,
and the second time period is different from the first time period.

20. The substrate processing apparatus of claim 18, wherein the grid includes a plurality of zones,
the control voltage bias include a plurality of different voltages and
each of the plurality of zones is configured to be individually controlled by the controller to receive a corresponding one of plurality of different voltages.

21. A manufacturing method of a semiconductor process comprising:
providing a series of process steps for manufacturing a semiconductor device;
providing a first substrate and a second substrate which are configured to be subject to the series of process steps;
performing a first process step, which is one of the series of process steps, on the first substrate and the second substrate;
after the performing of the first process step, performing a charge control process step, which is another of the series of process steps, on the first substrate and the second substrate; and
after the performing of the charge control process step, performing a second process step, which is yet another of the series of process steps, on the first substrate and the second substrate,
wherein:
the first substrate and the second substrate are subject to the charge control process step by using a first recipe and a second recipe which are different from each other, respectively, and
the first substrate and the second substrate are subject to the second process step by using a third recipe.

22. The manufacturing method of claim 21, wherein:
the first substrate is subject to the first process step by using a fourth recipe, and
the second substrate is subject to the first process step by using a fifth recipe which is different from the fourth recipe.

23. The manufacturing method of claim 21,
wherein the first process step includes:
determining whether to perform a sub-process step on the first substrate and the second substrate, and
based on the determination, performing the sub-process step or skipping the sub-process step, and
wherein the first and second substrates are subject to the first process step such that:
the first substrate is subject to the sub-process step, and
the second substrate is not subject to the sub-process step.
